(19) United States
(12) Patent Application Publication
(10) Pub. No.: US 2025/0386540 A1
(43) Pub. Date: Dec. 18, 2025

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Yu-Lun CHIU, Taichung City (TW); Jung-Ting CHEN, Zhubei City (TW); Tsung-Yu CHIANG, New Taipei City (TW)

(21) Appl. No.: 18/741,228

(22) Filed: Jun. 12, 2024

(51) Int. Cl. H01L 29/78; H01L 21/762; H01L 29/66

(52) U.S. Cl. CPC H10D 30/62; H01L 21/76232; H10D 30/024; H10D 64/021

(57) ABSTRACT

A method for forming a semiconductor device structure includes forming a fin structure over a substrate. The method also includes forming a fin structure over a substrate. The method also includes forming a gate structure across the fin structure. The method also includes forming source/drain epitaxial structures over opposite sides of the gate structure. The method also includes forming an inter-layer dielectric structure over the source/drain epitaxial structures. The method also includes removing a portion of the gate structure and the ILD structure to form an opening. The method also includes forming a blocking structure in the opening.

### BACKGROUND

Semiconductor devices are used in a variety of electronic applications, such as personal computers, cell phones, digital cameras, and other electronic equipment. Semiconductor devices are typically fabricated by sequentially depositing insulating or ILD structures, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective representation of forming a semiconductor device structure, in accordance with some embodiments of the disclosure.

FIGS. 2A-2E are cross-sectional representations of various stages of forming a semiconductor device structure, in accordance with some embodiments of the disclosure.

FIGS. 3A-3E are cross-sectional representations of various stages of forming a semiconductor device structure, in accordance with some embodiments of the disclosure.

FIG. 4 is a top view of forming a semiconductor device structure, in accordance with some embodiments of the disclosure.

FIGS. 5A-5B are cross-sectional representations of various stages of forming a semiconductor device structure, in accordance with some embodiments of the disclosure.

FIGS. 6A-6B are cross-sectional representations of various stages of forming a semiconductor device structure, in accordance with some embodiments of the disclosure.

FIG. 7 is a top view of forming a semiconductor device structure, in accordance with some embodiments of the disclosure.

FIG. 8 is a cross-sectional representation of forming a semiconductor device structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Fin structures described below may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments for forming a semiconductor device structure are provided. The method for forming the semiconductor device structure may include self-aligned forming a blocking structure in the gate structure and the contact structure 136. The blocking structure in the contact structure 136 may not be peeled, and the distance between the contact structures 136 may be reduced.

The semiconductor device structure may include various active devices. For example, the semiconductor device structure may include FinFET structures and gate all around (GAA) structures. The semiconductor device structure may also include channel structures such as nanosheet structures, forksheet structures, and CFET structures. The semiconductor device structure may also include Si and SiGe planar transistors.

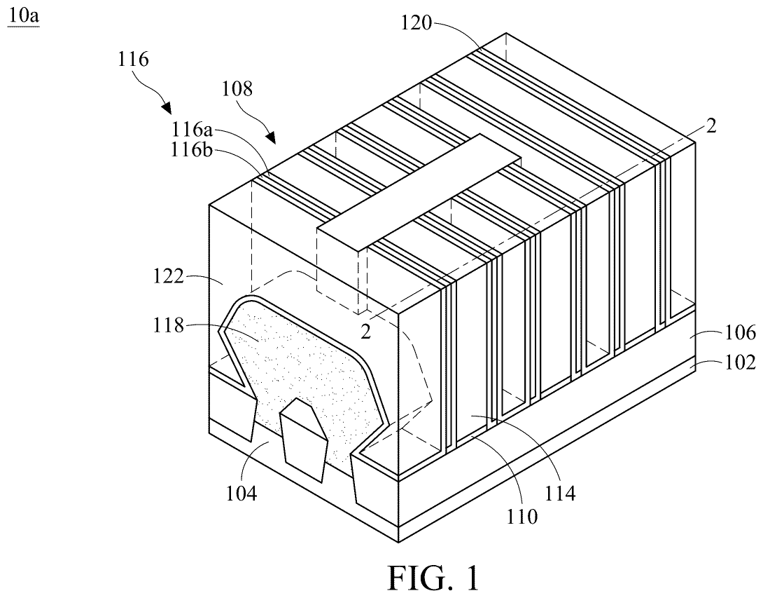

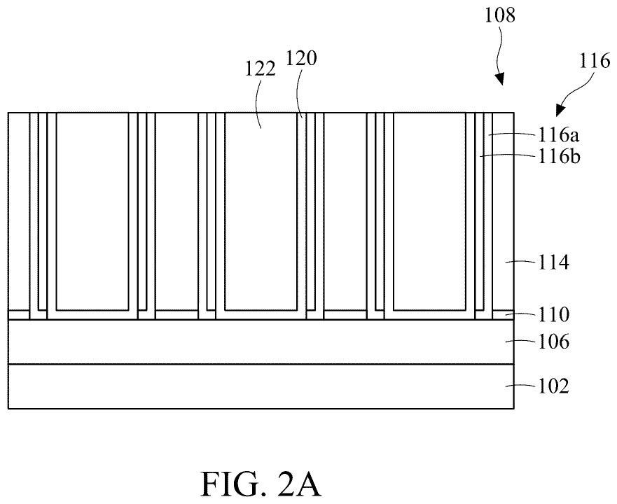

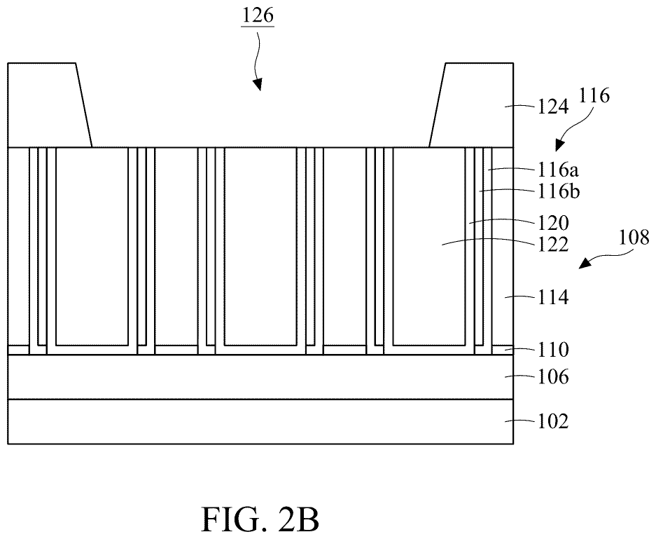

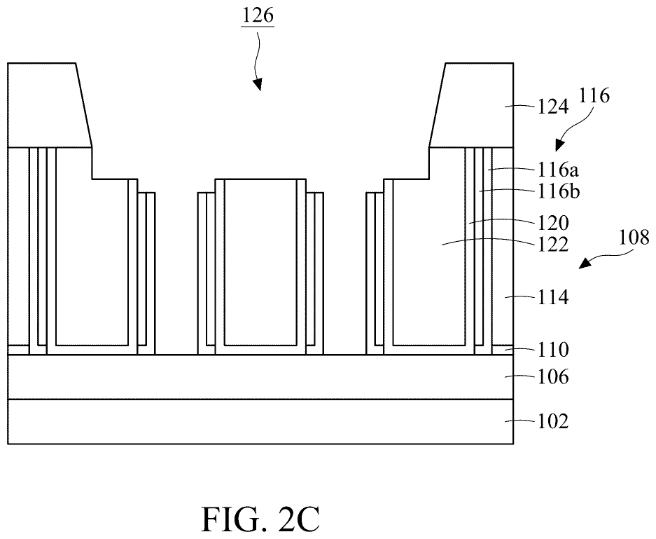

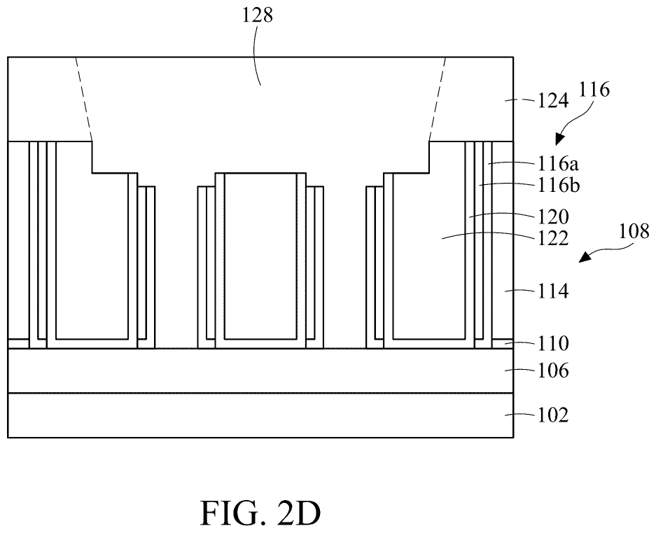

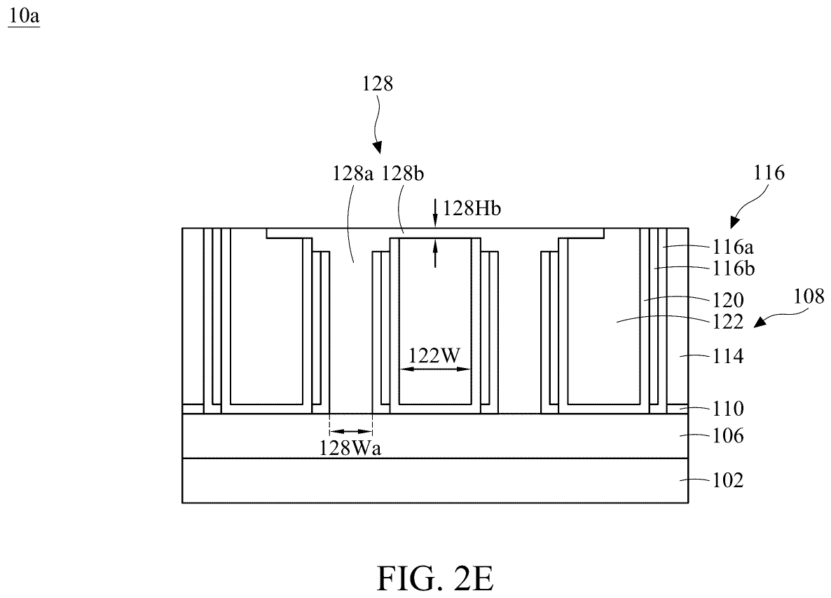

The semiconductor device structure 10a may be a FinFET structure. FIG. 1 is a perspective representation of forming a semiconductor device structure 10a, in accordance with some embodiments of the disclosure. FIGS. 2A-2E are cross-sectional representations of various stages of forming a semiconductor device structure 10a, in accordance with some embodiments of the disclosure. FIGS. 2A-2E show cross-sectional representations taken along line 2-2 in FIG. 1.

A substrate 102 is provided as shown in FIGS. 1 and 2A in accordance with some embodiments. The substrate 102 may be a semiconductor wafer such as a silicon wafer. The substrate 102 may also include other elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium nitride, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP. The substrate 102 may include an epitaxial layer. For example, the substrate 102 may be an epitaxial layer overlying a bulk semiconductor. In addition, the substrate 102 may also be semiconductor on insulator (SOI). The SOI substrate may be fabricated by a wafer bonding process, a silicon film transfer process, a separation by implantation of oxygen (SIMOX) process, other applicable methods, or a combination thereof. The substrate 102 may be an N-type substrate. The substrate 102 may be a P-type substrate.

Next, a pad layer may be blanketly formed over the substrate 102, and a hard mask layer may be blanketly formed over the pad layer (not shown). The pad layer may be a buffer layer between the substrate 102 and the hard mask layer. In addition, the pad layer may be used as a stop layer when the hard mask layer is removed. The pad layer may be made of silicon oxide. The hard mask layer may be made of silicon oxide, silicon nitride, silicon oxynitride, or another applicable material. The pad layer and the hard mask layer may be formed by deposition processes, such as a chemical vapor deposition (CVD) process, a high-density plasma chemical vapor deposition (HDPCVD) process, a spin-on process, a sputtering process, or another applicable process.

Afterwards, a photoresist layer may be formed over the hard mask layer (not shown). The photoresist layer may be patterned by a patterning process. The patterning process may include a photolithography process and an etching process. Examples of photolithography processes include photoresist coating (e.g., spin-on coating), soft baking, mask aligning, exposure, post-exposure baking, developing the photoresist, rinsing and drying (e.g., hard baking). The etching process may be a dry etching process or a wet etching process. As a result, a patterned pad layer and a patterned hard mask layer may be obtained. Afterwards, the patterned photoresist layer may be removed.

Afterwards, an etching process is performed on the substrate 102 to form a fin structure 104 by using the hard mask layer as a mask as shown in FIG. 1 in accordance with some embodiments. The etching process may be a dry etching process or a wet etching process. The dry etching process may include using a fluorine-based etchant gas, such as SF₆, CₓF_{y} (where x and y may be positive integers), NF₃, or a combination thereof. The etching process may be a time-controlled process, and continue until the fin structure 104 reaches a predetermined height. It should be noted that since the fin structure 104 and the substrate 102 may be made of the same material, and there may be no obvious interface between them.

Next, a liner layer may be conformally formed on the sidewalls and the top surface of the fin structure 104 (not shown). The liner layer may be used to protect the fin structure 104 from being damaged in the following processes (such as an anneal process or an etching process). In some embodiments, the liner layer is made of silicon nitride.

Next, an isolation layer 106 is formed to cover the fin structure 104 and the substrate 102 as shown in FIGS. 1 and 2A in accordance with some embodiments, The isolation layer 106 may be made of silicon oxide, silicon nitride, silicon oxynitride, fluoride-doped silicate glass (FSG), or another low-k dielectric material. The isolation layer 106 may be deposited by a deposition process, such as a chemical vapor deposition (CVD) process, a spin-on-glass process, or another applicable process.

Afterwards, the isolation layer 106 may be planarized to expose the top surface of the patterned hard mask layer (not shown). The isolation layer 106 may be planarized by a chemical mechanical polishing (CMP) process. Afterwards, the patterned hard mask layer may be removed. The patterned hard mask layer may be removed by a wet etching process. The wet etching process may include using a phosphoric acid (H₃PO₄) etching solution.

Next, an etching process is performed on the isolation layer 106, as shown in FIG. 1 in accordance with some embodiments. The etching process may be used to remove a portion of the liner layer and a portion of the isolation layer 106. As a result, the top portion of the fin structure 104 may be exposed and the remaining isolation layer 106 may surround the base portion of the fin structure 104. The remaining isolation layer 106 may be an isolation structure 106 such as a shallow trench isolation (STI) structure surrounding the base portion of the fin structure 104. The isolation structure 106 may be configured to prevent electrical interference or crosstalk.

Next, a dummy gate structure 108 is formed over and across the fin structures 104, as shown in FIGS. 1 and 2A in accordance with some embodiments. In some embodiments, the dummy gate structure 108 includes a dummy gate dielectric layer 132 110 and a dummy gate electrode layer 114. The dummy gate dielectric layer 132 and the dummy gate electrode layer may be replaced in the following steps to form a real gate structure with a high-k dielectric layer and a metal gate electrode layer.

The dummy gate dielectric layer 132 110 may include silicon oxide. The silicon oxide may be formed by an oxidation process (e.g., a dry oxidation process, or a wet oxidation process), a chemical vapor deposition process, other applicable processes, or a combination thereof. Alternatively, the dummy gate dielectric layer 132 110 may include a high-k dielectric layer (e.g., the dielectric constant is greater than 3.9) such as hafnium oxide (HfO₂). Alternatively, the high-k dielectric layer may include other high-k dielectrics, such as LaO, AlO, ZrO, TiO, Ta₂O₅, Y₂O₃, SrTiO₃, BaTiO₃, BaZrO, HfZrO, HfLaO, HfTaO, HfSiO, HfSiON, HfTiO, LaSiO, AlSiO, (Ba, Sr)TiO₃, Al₂O₃, other applicable high-k dielectric materials, or a combination thereof. The high-k dielectric layer may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

The dummy gate electrode layer 114 may include polycrystalline-silicon (poly-Si), poly-crystalline silicon-germanium (poly-SiGe), metals (e.g., tungsten, titanium, aluminum, copper, molybdenum, nickel, platinum, the like, or a combination thereof), metal alloys, metal-nitrides (e.g., tungsten nitride, molybdenum nitride, titanium nitride, and tantalum nitride, the like, or a combination thereof), metal-silicides (e.g., tungsten silicide, titanium silicide, cobalt silicide, nickel silicide, platinum silicide, erbium silicide, the like, or a combination thereof), metal-oxides (e.g., ruthenium oxide, indium tin oxide, the like, or a combination thereof), other applicable materials, or a combination thereof. The dummy gate electrode layer 114 may be formed by a chemical vapor deposition process (e.g., a low pressure chemical vapor deposition process, or a plasma enhanced chemical vapor deposition process), a physical vapor deposition process (e.g., a vacuum evaporation process, or a sputtering process), other applicable processes, or a combination thereof.

Afterwards, an etching process may be performed on the dummy gate dielectric layer 132 110 and the dummy gate electrode layer 114 to form the dummy gate structure 108 by using a patterned photoresist layer as a mask (not shown). The etching process may be a dry etching process or a wet etching process. The dummy gate dielectric layer 132 110 and the dummy gate electrode layer 114 may be etched by a dry etching process. The dry etching process may include using a fluorine-based etchant gas, such as SF₆, CₓF_{y} (where x and y may be positive integers), NF₃, or a combination thereof. After the etching process, the top portion of the fin structure 104 may be exposed on opposite sides of the dummy gate structure 108.

Next, a pair of spacer layers 116 is formed on opposite sidewalls of the dummy gate structure 108, as shown in FIGS. 1 and 2A in accordance with some embodiments. The spacer layers 116 may be a multi-layer structure. In some embodiments, the spacer layers 116 include a first spacer layer 116a and a second spacer layer 116b. The first spacer layer 116a and the second spacer layer 116b may be made of silicon oxide, silicon nitride, silicon oxynitride, and/or dielectric materials. The first spacer layer 116a may be deposited over the sidewalls of the dummy gate structure 108, and the second spacer layer 116b may be deposited over the first spacer layer 116a. The spacer layers 116 may be formed by a chemical vapor deposition (CVD) process, a spin-on-glass process, or another applicable process.

Afterwards, the top portion of the fin structure 104 exposed on opposite sides of the dummy gate structure 108 may be removed in an etching process to form a recess (not shown). The etching process may be a dry etching process or a wet etching process. The fin structures 104 may be etched by a dry etching process. The dry etching process may include using a fluorine-based etchant gas, such as SF₆, CₓF_{y} (where x and y may be positive integers), NF₃, or a combination thereof.

Next, a source/drain epitaxial structure 118 is formed in the recess over the fin structure 104 on opposite sides of the dummy gate structure 108, as shown in FIG. 1 in accordance with some embodiments. A strained material may be grown in the recess by an epitaxial (epi) process to form the source/drain epitaxial structure 118. In addition, the lattice constant of the strained material may be different from the lattice constant of the substrate 102. The source/drain epitaxial structure 118 may include Ge, SiGe, InAs, InGaAs, InSb, GaAs, GaSb, InAlP, InP, SiC, SiP, other applicable materials, or a combination thereof. The source/drain epitaxial structure 118 may be formed by an epitaxial growth step, such as metalorganic chemical vapor deposition (MOCVD), metalorganic vapor phase epitaxy (MOVPE), plasma-enhanced chemical vapor deposition (PECVD), remote plasma-enhanced chemical vapor deposition (RP-CVD), molecular beam epitaxy (MBE), hydride vapor phase epitaxy (HVPE), liquid phase epitaxy (LPE), chloride vapor phase epitaxy (Cl-VPE), or any other suitable method. The source/drain epitaxial structure 118 may refer to a source or a drain, individually or collectively dependent upon the context.

Afterwards, an etch stop layer 120 is formed over the spacer layers 116 and the source/drain epitaxial structure 118, as shown in FIGS. 1 and 2A in accordance with some embodiments. The etch stop layer 120 may include silicon nitride, silicon oxide, silicon oxynitride (SiON), other applicable materials, or a combination thereof. The etch stop layer 120 may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

After the source/drain epitaxial structure 118 is formed, an inter-layer dielectric (ILD) structure 122 is formed to cover the source/drain epitaxial structure 118 and fill up a space between the etch stop layer 120, as shown in FIGS. 1 and 2A in accordance with some embodiments. The ILD structure 122 may surround the fin structure 104 and the source/drain epitaxial structure 118.

The ILD structure 122 may include multilayers made of multiple dielectric materials, such as silicon oxide (SiOₓ, where x may be a positive integer), silicon oxycarbide (SiCO_{y}, where y may be a positive integer), silicon oxycarbonitride (SiNCO_{z}, where z may be a positive integer), silicon nitride, silicon oxynitride, phosphosilicate glass (PSG), borophosphosilicate glass (BPSG), low-k dielectric material, or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD structure 122 may be formed by chemical vapor deposition (CVD), spin-on coating, or other applicable processes.

Afterwards, a planarizing process is performed on the ILD structure 122 until the top surface of the dummy gate structure 108 is exposed, as shown in FIGS. 1 and 2A in accordance with some embodiments. After the planarizing process, the top surface of the dummy gate structure 108 may be substantially level with the top surfaces of the spacer layers 116 and the ILD structure 122. The planarizing process may include a grinding process, a chemical mechanical polishing (CMP) process, an etching process, other applicable processes, or a combination thereof.

Next, a hard mask layer 124 is formed over the dummy gate structure 108 and the ILD structure 122, and an opening 126 is formed in the hard mask layer 124, as shown in FIG. 2B in accordance with some embodiments. The hard mask layer 124 may define the position of substantially formed blocking structure. In some embodiments, the sidewall of the hard mask layer 124 is laterally shifted from the sidewall of the ILD structure 122.

The hard mask layer 124 may be a single layer or a multi-layer structure. The hard mask layer 124 may include SiN, Si, nitrides, oxides, other suitable dielectric materials, or a combination thereof. The hard mask layer 124 may be formed by a chemical vapor deposition process (CVD), a physical vapor deposition process (PVD), (e.g., evaporation or sputter), an atomic layer deposition process (ALD), an electroplating process, other suitable processes, or a combination thereof.

A portion of the dummy gate structure 108 and the ILD structure 122 may be exposed from the opening 126. The hard mask layer 124 may be patterned by a photolithography process, which may include exposure, developing, rinsing, and baking processes. The hard mask layer 124 may be etched by a dry etching process. After the etching process, a wet clean process is performed to remove the residue of the etching process. The wet clean process may use DI, H₂O₂, H₂O, HF, H₂PO₄, HCl, CH₂CHOOH, H₂SO₄, HNO₃, other applicable chemicals, or a combination thereof to remove the residue of the etching process.

Next, the dummy gate structure 108 exposed from the opening 126 is removed, as shown in FIG. 2C in accordance with some embodiments. In some embodiments, the top portions of the ILD structure 122, the etch stop layer 120, and the spacer layers 116 exposed from the opening 126 are also removed. The lower portion of the ILD structure 122 may remain after forming the opening 126. In some embodiments, the top surface of the isolation structure 106 is exposed from the opening 126. The dummy gate structure 108, the top portion of the ILD structure 122, the etch stop layer 120, and the spacer layers 116 may be removed by a dry etching process or a wet etching process.

Afterwards, a blocking material 128 is filled in the opening 126, as shown in FIG. 2D in accordance with some embodiments. The blocking material 128 may be made of SiN, SiCN, SiCON, SiO₂, other suitable materials, or a combination thereof. Since the blocking material 128 and the hard mask layer 124 may be formed by the same material, the boundary between the blocking material 128 and the hard mask layer 124 may be invisible and is shown as a dashed line. The blocking material 128 may be deposited by using CVD, ALD, other applicable methods, or a combination thereof.

Next, the hard mask layer 124 over the dummy gate structure 108 is removed by a planarizing process, and the blocking structure 128 is formed, as shown in FIG. 2E in accordance with some embodiments. The blocking structure 128 includes a first portion 128a formed between the spacer layers 116 and a second portion 128b formed over the ILD structure 122. The first portion 128a of the blocking structure 128 may be referred as the gate blocking structure 128a. The gate blocking structure 128a may isolate adjacent gate structures 130 108. The second portion 128b of the blocking structure 128 may be referred as the contact blocking structure 128b. The contact blocking structure 128b may isolate adjacent subsequently formed contact structures 136. The planarizing process may include a grinding process, a chemical mechanical polishing (CMP) process, an etching process, other applicable processes, or a combination thereof.

In some embodiments, the blocking structure 128 is formed across the ILD structure 122. In some embodiments, the blocking structure 128 covers the ILD structure 122. In some embodiments, the gate blocking structure 128a extends between the spacer layers 116. In some embodiments, the bottom surface of the gate blocking structure 128a is lower than the bottom surface of the contact blocking structure 128b.

In some embodiments, the gate blocking structure 128a has a width 128Wa in a range of about 1 nm to about 20 nm. If the gate blocking structure 128a is too wide, the device area may be too great. If the gate blocking structure 128a is too narrow, it may be difficult to remove the dummy gate structure 108 in the opening 126.

In some embodiments, the ILD structure 122 under the blocking structure 128 has a width 122W in a range of about 5 nm to about 30 nm. If the ILD structure 122 is too wide, the blocking structure 128 formed over the ILD structure 122 may be too thin, and the contact blocking structure 128 may not isolate adjacent subsequently formed contact structures 136.

In some embodiments, the contact blocking structure 128b has a thickness 128Hb in a range of about 0.5 nm to about 50 nm. If the contact blocking structure 128 is too thin, the contact blocking structure 128 may not isolate adjacent subsequently formed contact structures 136.

Next, the dummy gate structure 108 may be removed, and a gate structure 130 may be formed between the spacer layers 116. The gate structures 130 may be multi-layered structures. Each of the gate structures 130 may include an interfacial layer, a gate dielectric layer 132, a work function layer 134, and a gate electrode layer.

The interfacial layer may be formed over the exposed portions of the base fin structures. The interfacial layer may be made of silicon oxide, and the interfacial layer may be formed by thermal oxidation.

The gate dielectric layer 132 may be formed over the interfacial layer. In addition, the gate dielectric layer 132 may also cover the sidewalls of the spacer layers 116. The gate dielectric layer 132 may be made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂-Al₂O₃) alloy, other applicable high-k dielectric materials, or a combination thereof. The gate dielectric layer 132 may be formed using CVD, ALD, other applicable methods, or a combination thereof.

Next, the work function layer 134 may be conformally formed over the gate dielectric layer 132. The work function layer 134 may be made of a metal material. The metal material of the work function layer 134 formed in the second region in the substrate 102 may include an N-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), or a combination thereof.

The metal material of the work function layer 134 formed in the first region in the substrate 102 may include a P-work-function metal. The P-work-function metal may include titanium nitride (TiN), tungsten nitride (WN), tantalum nitride (TaN), ruthenium (Ru), or a combination thereof. The work function layer 134 may be formed using CVD, ALD, other applicable methods, or a combination thereof.

Next, a gate electrode layer may be formed over the work function layer 134. The gate electrode layer may be made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. The gate electrode layer may be formed using CVD, ALD, electroplating, another applicable method, or a combination thereof. After the gate electrode layer is formed, a planarization process such as CMP or an etch-back process may be performed.

A second contact blocking structure may be optionally formed over the source/drain epitaxial structures 118. In some embodiments, the second contact blocking structure is separated from the gate blocking structure 128a. The second contact blocking structure may be formed by depositing the contact blocking structure material first, and the contact blocking structure material may be patterned and etched. The second contact blocking structure may include SiN, SiCN, SiCON, SiO₂, other suitable materials, or a combination thereof. The patterning process may include a photolithography process and an etching process. Examples of photolithography processes include photoresist coating (e.g., spin-on coating), soft baking, mask aligning, exposure, post-exposure baking, developing the photoresist, rinsing and drying (e.g., hard baking). The etching process may be a dry etching process or a wet etching process.

Next, an opening may be formed in the ILD structure 122 over the source/drain epitaxial structures 118. A barrier layer may be conformally formed over the bottom surface and the sidewalls of the opening. The barrier layer may be formed before filling the conductive material in the opening to prevent the conductive material from diffusing out. The barrier layer may also serve as an adhesive or glue layer. The material of the barrier layer may be TiN, Ti, other applicable materials, or a combination thereof. The barrier layer may be formed by depositing the barrier layer materials by a physical vapor deposition process (PVD) (e.g., evaporation or sputtering), an atomic layer deposition process (ALD), an electroplating process, other applicable processes, or a combination thereof.

Next, a silicide structure may be formed in the source/drain epitaxial structure 118. The silicide structure may reduce the contact resistance between the source/drain epitaxial structure 118 and the subsequently formed contact structure 136 over the source/drain epitaxial structure 118.

The silicide structure may be made of TiSi, Ti₅Si₄, TiSi₂, NiSi, NiSi₂, CoSi, CoSi₂, WSi₂ and MoSi₂, or other suitable low-resistance materials. The silicide structure may be formed over the source/drain epitaxial structure 118 by forming a metal layer over the source/drain epitaxial structure 118 first. The metal layer may react with the source/drain epitaxial structure 118 in an annealing process and a silicide layer may be produced. Afterwards, the unreacted metal layer may be removed in an etching process and the silicide structure may be formed over the source/drain epitaxial structure 118.

Afterwards, a contact structure 136 is formed into the opening over the source/drain epitaxial structure 118. The contact structure 136 may be made of a metal material (e.g., Co, Ni, W, Ti, Ta, Cu, Al, Ru, Mo, TiN, TaN, and/or a combination thereof), metal alloys, poly-Si, other applicable conductive materials, or a combination thereof. The contact structure 136 may be formed by a CVD process, a PVD process, an ALD process, an electroplating process, another suitable process, or a combination thereof to deposit the conductive materials of the contact structure 136, and then a planarization process such as a chemical mechanical polishing (CMP) process or an etch back process is optionally performed to remove excess conductive materials. After the planarization process, the top surface of the contact structure 136 may be level with the top surface of the gate spacer layers 116.

By self-aligned forming a contact blocking structure 128b near the gate blocking structure 128a after forming the dummy gate structure 108, the contact blocking structure 128b may not be peeled, and the distance between the contact structures 136 may be minimized.

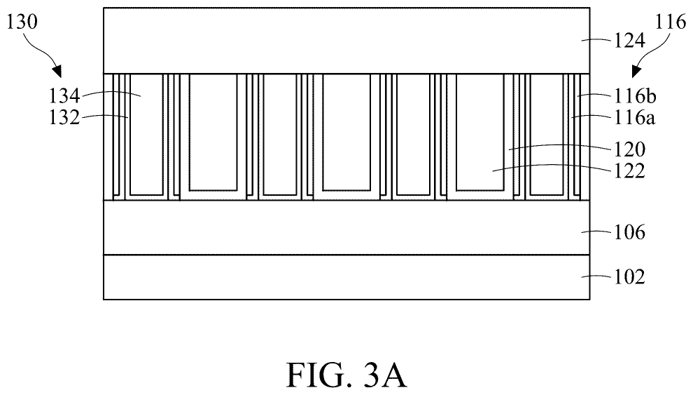

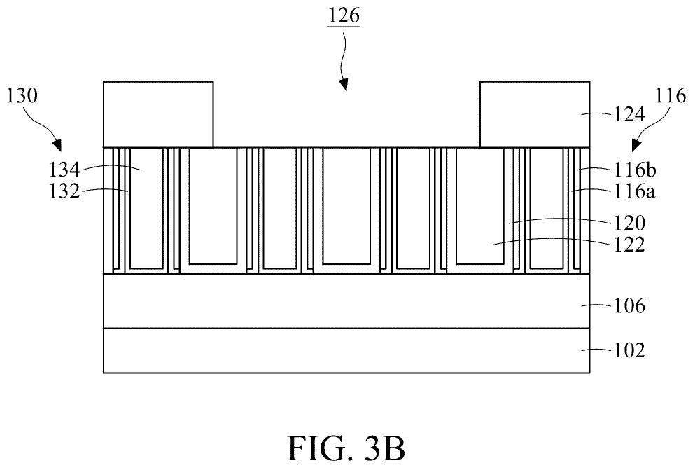

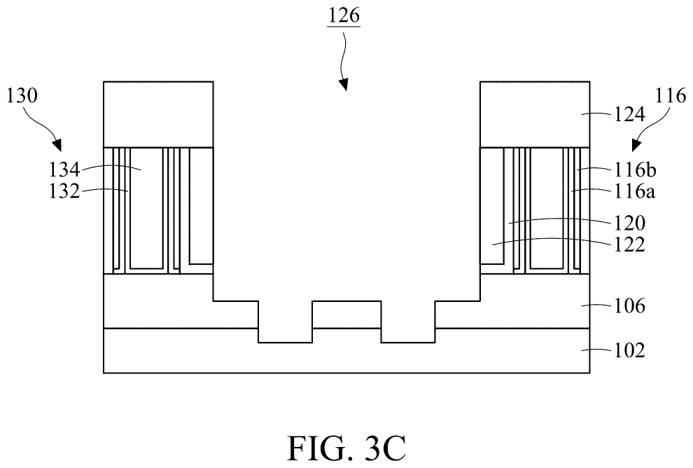

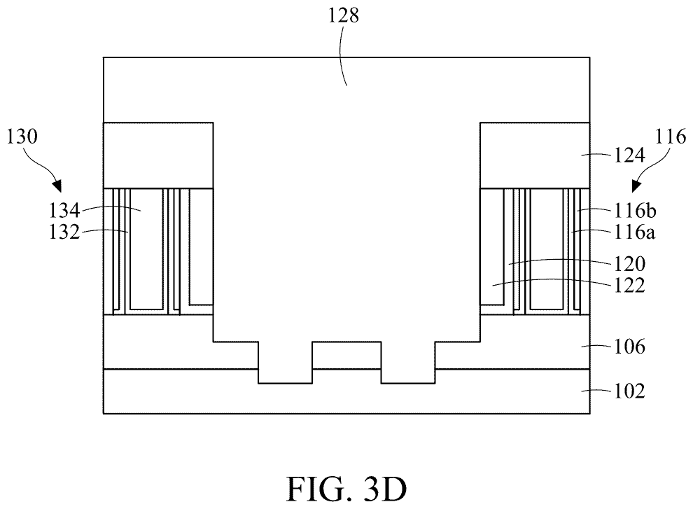

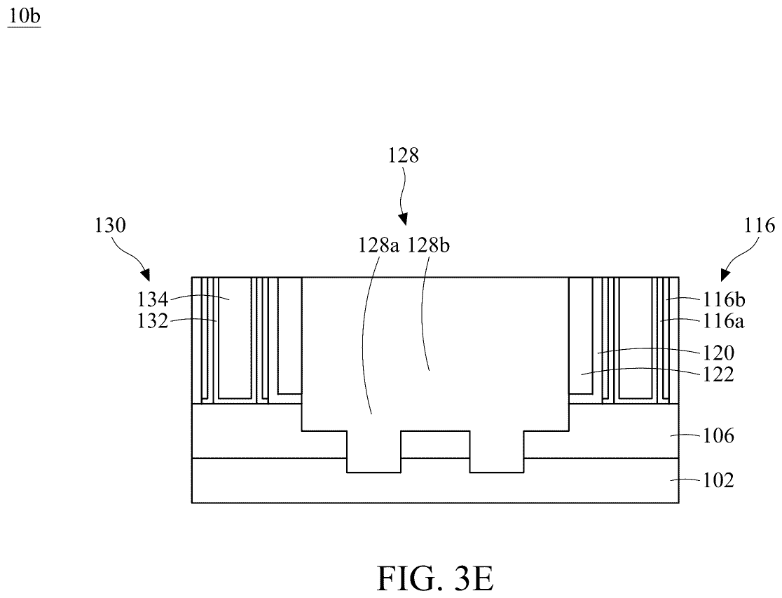

Many variations and/or modifications may be made to the embodiments of the disclosure. FIGS. 3A-3E are cross-sectional representations of various stages of forming a semiconductor device structure 10b, in accordance with some embodiments of the disclosure. Some processes or devices are the same as, or similar to, those described in the embodiments above, and therefore the descriptions of these processes and devices are not repeated herein. The difference from the embodiments described above is that, as shown in FIG. 3A in accordance with some embodiments, the blocking structure 128 is formed after forming the gate structure 130.

The gate structure 130 is formed between the spacer layers 116. Each of the gate structures 130 may include an interfacial layer, a gate dielectric layer 132, a work function layer 134, and a gate electrode layer, as shown in FIG. 3A in accordance with some embodiments.

The hard mask layer 124 is deposited over the gate structure 130 and the ILD structure 122 after forming the gate structure 130, as shown in FIG. 3A in accordance with some embodiments. The processes for forming the hard mask layer 124 may be the same as, or similar to, those used to form the hard mask layer 124 in the previous embodiments. For the purpose of brevity, the descriptions of these processes are not repeated herein. In some embodiments, the hard mask layer 124 is a multi-layer structure.

Next, an opening 126 is formed in the hard mask layer 124, as shown in FIG. 3B in accordance with some embodiments. A portion of the gate structure 130 and the ILD structure 122 may be exposed from the opening 126.

Afterwards, the gate structure 130 and the ILD structure 122 exposed from the opening 126 is removed, as shown in FIG. 3C in accordance with some embodiments. In some embodiments, the etch stop layer 120 and the spacer layers 116 exposed from the opening 126 are also removed. In addition, the isolation structure 106 and the substrate 102 exposed from the opening 126 are also further recessed.

Since the etching rates of the gate structure 130 and the ILD structure 122 are different, the amount of the gate structure 130 and the ILD structure 122 consumed in the etching process may be different. Therefore, the substrate 102 under the gate structure 130 exposed from the opening 126 is further recessed, as shown in FIG. 3C in accordance with some embodiments. In some embodiments, the substrate 102 under the ILD structure 122 exposed from the opening 126 remains.

Next, the blocking structure material 128 is deposited in the opening 126, as shown in FIG. 3D in accordance with some embodiments. The hard mask layer 124 over the gate structure 130 is removed by a planarization process, and the blocking structure 128 is formed, as shown in FIG. 3E in accordance with some embodiments. The blocking structure 128 includes the gate blocking structure 128a protruding in the substrate 102 and the contact blocking structure 128b formed over the isolation structure 106. The gate blocking structure 128a may isolate adjacent gate structures 130 108, and the contact blocking structure 128b may isolate adjacent subsequently formed contact structures 136.

In some embodiments, the bottom portion of the gate blocking structure 128 extends from the bottom surface of the contact blocking structure 128b. In some embodiments, the bottom surface of the blocking structure 128 is lower than the bottom surface of the ILD structure 122.

By self-aligned forming a contact blocking structure 128b near the gate blocking structure 128a after forming the gate structure 130, the contact blocking structure 128b may not be peeled, and the distance between the contact structures 136 may be minimized.

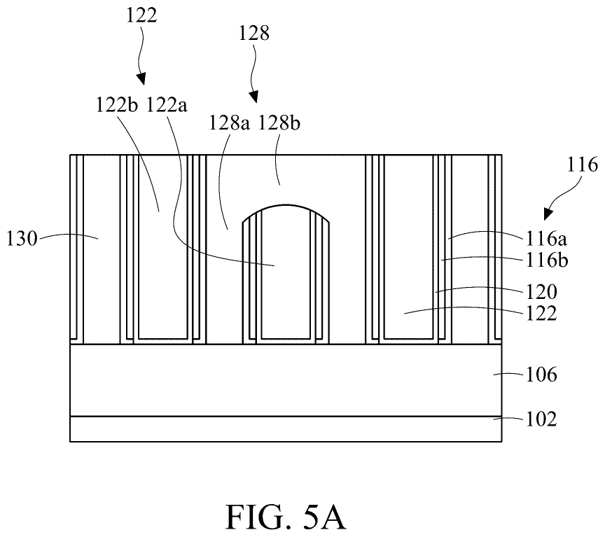

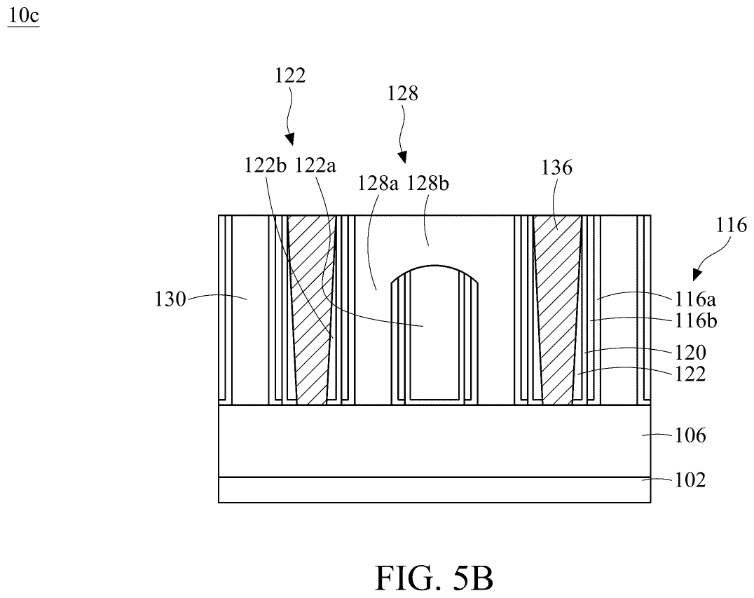

Many variations and/or modifications may be made to the embodiments of the disclosure. FIGS. 5A-5B are cross-sectional representations of various stages of forming a semiconductor device structure 10c, in accordance with some embodiments of the disclosure. Some processes or devices are the same as, or similar to, those described in the embodiments above, and therefore the descriptions of these processes and devices are not repeated herein. The difference from the embodiments described above is that, as shown in FIG. 5A in accordance with some embodiments, the spacer layers 116 and the ILD structure 122 over sidewalls of the blocking structure 128 is not consumed when forming the opening 126.

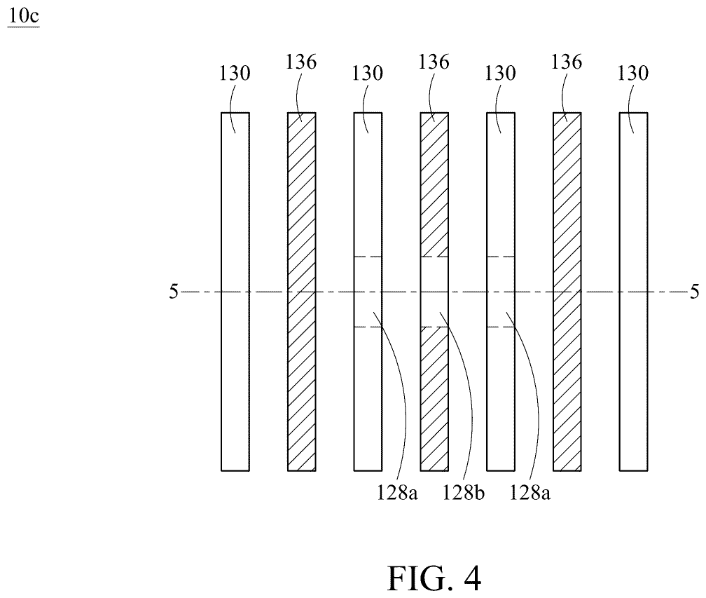

FIG. 4 is a top view of a semiconductor device structure 10c, in accordance with some embodiments of the disclosure. FIGS. 5A-5B are cross-sectional representations of various stages of forming a semiconductor device structure 10c, in accordance with some embodiments of the disclosure. FIGS. 5A-5B show cross-sectional representations taken along line 5-5 in FIG. 4.

After forming the gate structure 130, the contact structure 136 is formed in the ILD structure 122 over the source/drain epitaxial structure 118, as shown in FIG. 5B in accordance with some embodiments.

After forming the opening 126, the sidewalls of the hard mask layer 124 defining the position of the blocking structure 128 may be aligned with the sidewalls of the spacer layers 116. The ILD structure 122 may include a first portion 122a covered by the blocking structure 128, and a second portion 122b adjacent to the blocking structure 128.

In some embodiments, the blocking structure 128 has straight sidewalls. In some embodiments, the gate blocking structure 128a has straight sidewalls. The top corners of the first portion 122a of the ILD structure 122 may be consumed when forming the opening 126. In some embodiments, the first portion 122a of the ILD structure 122 has a convex curved top surface. In some embodiments, the contact blocking structure 128b has a concave curved bottom surface. In some embodiments, the top corners of the first portion 122a of the ILD structure 122 are rounded.

By self-aligned forming a contact blocking structure 128b near the gate blocking structure 128a, the contact blocking structure 128b may not be peeled, and the distance between the contact structures 136 may be minimized. The blocking structure 128 may have straight sidewalls and the first portion 122a of the ILD structure 122 may have a convex curved top surface.

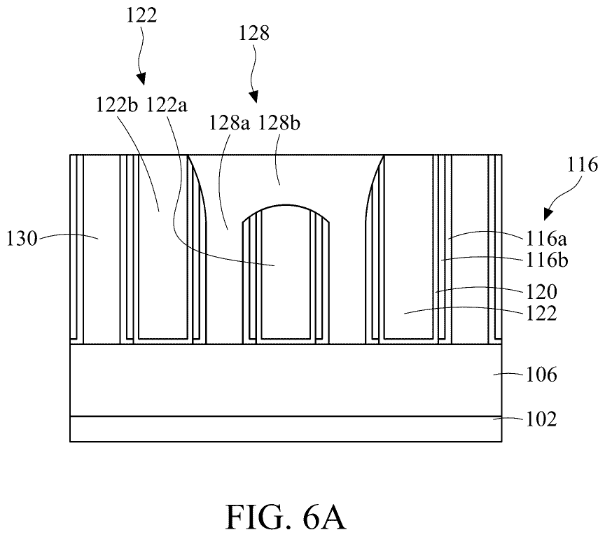

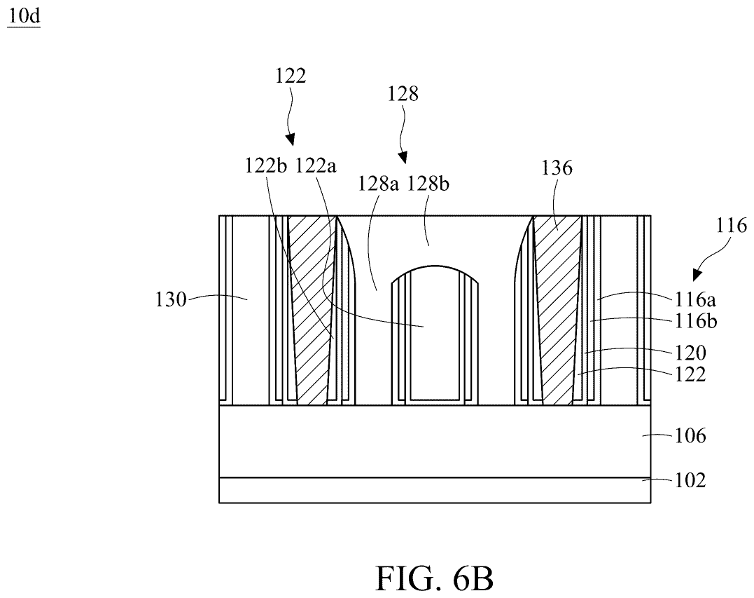

Many variations and/or modifications may be made to the embodiments of the disclosure. FIGS. 6A-6B are cross-sectional representations of various stages of forming a semiconductor device structure 10d, in accordance with some embodiments of the disclosure. Some processes or devices are the same as, or similar to, those described in the embodiments above, and therefore the descriptions of these processes and devices are not repeated herein. The difference from the embodiments described above is that, as shown in FIG. 6A in accordance with some embodiments, the spacer layers 116 and the ILD structure 122 over sidewalls of the blocking structure 128 are consumed when forming the opening 126.

After forming the gate structure 130, the contact structure 136 is formed in the ILD structure 122 over the source/drain epitaxial structure 118, as shown in FIG. 6B in accordance with some embodiments.

In some embodiments, the blocking structure 128 has curved sidewalls. In some embodiments, the gate blocking structure 128a has curved sidewalls. In some embodiments, the second portion 122b of the ILD structure 122 adjacent to the blocking structure is consumed. In some embodiments, the blocking structure 128 covers top surfaces of the spacer layers 116 formed over sidewalls of the blocking structure 128. In some embodiments, the top surface of the second spacer layer 116b is higher than the top surface of the first spacer layer 116a.

In some embodiments, the top portion of the blocking structure 128 is wider than the bottom portion of the blocking structure 128.

In some embodiments, the ratio of the width of the top surface and the width of the bottom surface of the second portion 122b of the ILD structure 122 is in a range of about 0.5 to about 1.0. If the ratio is too less, the contact structure 136 formed in the second portion 122b of the ILD structure 122 may be blocked.

By self-aligned forming a contact blocking structure 128b near the gate blocking structure 128a, the contact blocking structure 128b may not be peeled, and the distance between the contact structures 136 may be minimized. The blocking structure 128 may have curved sidewalls.

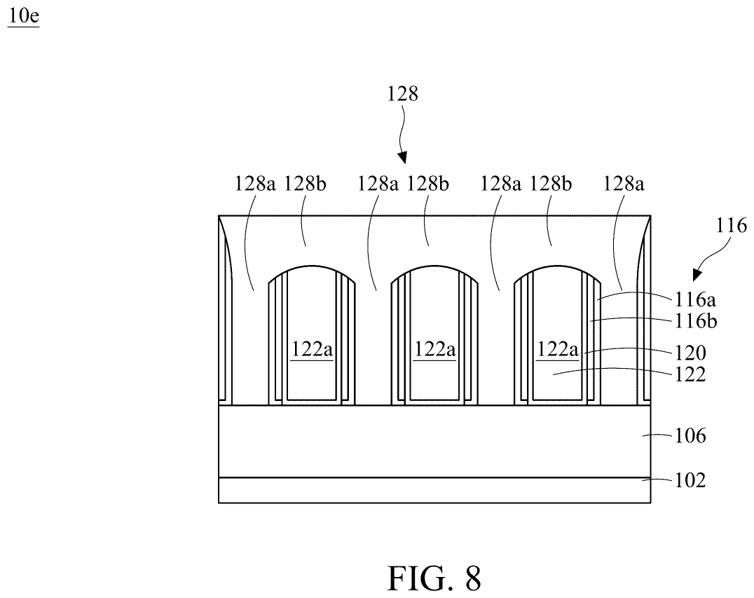

Many variations and/or modifications may be made to the embodiments of the disclosure. FIG. 8 is a cross-sectional representation of a semiconductor device structure 10e, in accordance with some embodiments of the disclosure. Some processes or devices are the same as, or similar to, those described in the embodiments above, and therefore the descriptions of these processes and devices are not repeated herein. The difference from the embodiments described above is that, as shown in FIG. 8 in accordance with some embodiments, multiple contact blocking structures 128b is formed over the first portion 122a of the ILD structure 122.

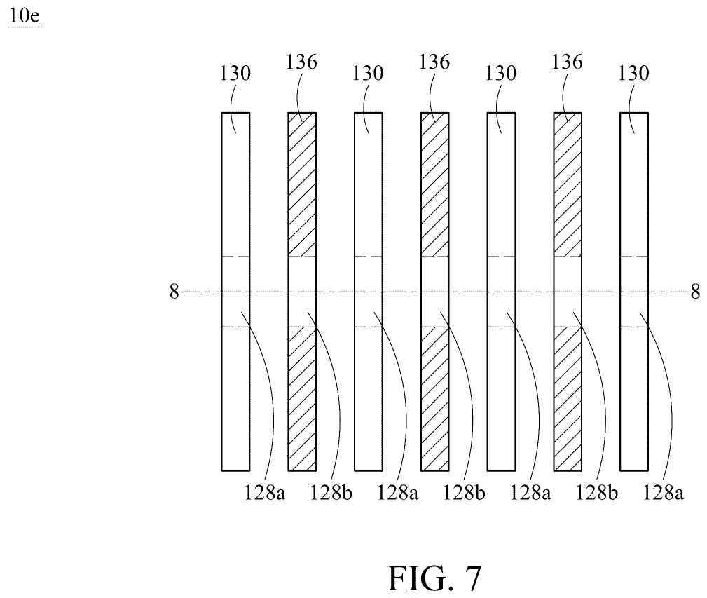

FIG. 7 is a top view of a semiconductor device structure 10e, in accordance with some embodiments of the disclosure. FIG. 8 is a cross-sectional representation of a semiconductor device structure 10e, in accordance with some embodiments of the disclosure. FIG. 8 show cross-sectional representations taken along line 8-8 in FIG. 7.

It should be noted that, although there are three contact blocking structures 128b, the number of the contact blocking structure 128b are not limited herein, depending on the demand of design and process.

In some embodiments, the blocking structure 128 is formed across multiple first portions 122a of the ILD structure 122. In some embodiments, the first portion 122a of the ILD structure 122 has a convex curved top surface. In some embodiments, the blocking structure 128 has curved sidewalls. In some embodiments, the gate blocking structure 128a has curved sidewalls.

By self-aligned forming a contact blocking structure 128b near the gate blocking structure 128a, the contact blocking structure 128b may not be peeled, and the distance between the contact structures 136 may be minimized. Multiple contact blocking structures 128b may be formed over the first portions 122a of the ILD structure 122.

As described previously, the contact blocking structure 128b are self-aligned formed when forming the gate blocking structure 128a. The defect of the contact blocking structure 128b may be prevented, and the distance between the contact structures 136 may be minimized. In some embodiments as shown in FIG. 3, the blocking structure 128 further extends into the substrate 102 and the isolation structure 106. In some embodiments as shown in FIG. 5, the blocking structure 128 has straight sidewalls. In some embodiments as shown in FIG. 6, the blocking structure 128 has curved sidewalls. In some embodiments as shown in FIG. 8, multiple contact blocking structure 128b are formed.

Embodiments of a semiconductor device structure and a method for forming the same are provided. The contact blocking structure may be self-aligned formed when forming adjacent gate blocking structure. The defect of forming the contact blocking structure may be reduced, and the distance between contact structures may be minimized.

In some embodiments, a method for forming a semiconductor device structure is provided. The method for forming a semiconductor device structure includes forming a fin structure over a substrate. The method for forming a semiconductor device structure also includes forming a gate structure across the fin structure. The method for forming a semiconductor device structure also includes forming source/drain epitaxial structures over opposite sides of the gate structure. The method for forming a semiconductor device structure also includes forming an inter-layer dielectric (ILD) structure over the source/drain epitaxial structures. The method for forming a semiconductor device structure also includes removing a portion of the gate structure and the ILD structure to form an opening. The method for forming a semiconductor device structure also includes forming a blocking structure in the opening.

In some embodiments, a method for forming a semiconductor device structure is provided. The method for forming a semiconductor device structure includes forming a fin structure over a substrate. The method for forming a semiconductor device structure also includes forming a gate structure across the fin structure. The method for forming a semiconductor device structure also includes forming an isolation structure surrounding a bottom portion of the fin structure. The method for forming a semiconductor device structure also includes forming a gate structure across the fin structure. The method for forming a semiconductor device structure also includes forming spacer layers over opposite sides of the gate structure. The method for forming a semiconductor device structure also includes forming source/drain epitaxial structures beside the gate structure. The method for forming a semiconductor device structure also includes forming an ILD structure over the source/drain epitaxial structures. The method for forming a semiconductor device structure also includes forming a mask layer with an opening exposing the ILD structure and the gate structure. The method for forming a semiconductor device structure also includes etching the ILD structure and the gate structure to from the opening to expose the top surface of the isolation structure. The method for forming a semiconductor device structure also includes filling the opening with a blocking material to form a blocking structure.

In some embodiments, a semiconductor device structure is provided. The semiconductor device structure includes a fin structure extending in a first direction formed over a substrate. The semiconductor device structure also includes a gate structure formed across the fin structure, wherein the gate structure extends in a second direction perpendicular to the first direction. The semiconductor device structure also includes source/drain epitaxial structures formed on opposite sides of the gate structure. The semiconductor device structure also includes an ILD structure formed over the source/drain epitaxial structures. The semiconductor device structure also includes a contact structure 136 formed through the ILD structure over the source/drain epitaxial structures. The semiconductor device structure also includes a blocking structure formed in the gate structure and the contact structure 136. The blocking structure has an extending bottom portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a fin structure over a substrate;
forming a gate structure across the fin structure;
forming source/drain epitaxial structures over opposite sides of the gate structure;
forming an inter-layer dielectric (ILD) structure over the source/drain epitaxial structures;
removing a portion of the gate structure and the ILD structure to form an opening; and
forming a blocking structure in the opening.

2. The method for forming the semiconductor device structure as claimed in claim 1, further comprising:
forming an isolation structure surrounding a bottom portion of the fin structure; and
removing the isolation structure when forming the opening.

3. The method for forming the semiconductor device structure as claimed in claim 1, wherein the etching rates of the ILD structure and the gate structure are different when forming the opening.

4. The method for forming the semiconductor device structure as claimed in claim 1, wherein a lower portion of the ILD structure remains after forming the opening.

5. The method for forming the semiconductor device structure as claimed in claim 1, further comprising:
forming a mask layer over the gate structure and the ILD structure,
wherein a sidewall of the mask layer is laterally shifted from a sidewall of the ILD structure.

6. The method for forming the semiconductor device structure as claimed in claim 1, wherein top corners of the ILD structure are rounded when forming the opening.

7. The method for forming the semiconductor device structure as claimed in claim 1, further comprising:
forming spacer layers over opposite sides of the gate structure,
wherein top portions of the spacer layers are consumed when removing the gate structure and the ILD structure.

8. A method for forming a semiconductor device structure, comprising:
forming a fin structure over a substrate;
forming an isolation structure surrounding a bottom portion of the fin structure;
forming a gate structure across the fin structure;
forming spacer layers over opposite sides of the gate structure;
forming source/drain epitaxial structures beside the gate structure;
forming an ILD structure over the source/drain epitaxial structures;
forming a mask layer with an opening exposing the ILD structure and the gate structure;
etching the ILD structure and the gate structure to from the opening to expose a top surface of the isolation structure; and
filling the opening with a blocking material to form a blocking structure.

9. The method for forming the semiconductor device structure as claimed in claim 8, wherein the blocking structure have straight sidewalls.

10. The method for forming the semiconductor device structure as claimed in claim 8, wherein the gate structure and the ILD structure are removed from the opening.

11. The method for forming the semiconductor device structure as claimed in claim 8, wherein a top portion of the blocking structure is wider than a bottom portion of the blocking structure.

12. The method for forming the semiconductor device structure as claimed in claim 8, wherein the blocking structure is formed across the ILD structure.

13. A semiconductor structure, comprising:
a fin structure extending in a first direction formed over a substrate;
a gate structure formed across the fin structure, wherein the gate structure extends in a second direction perpendicular to the first direction;
source/drain epitaxial structures formed on opposite sides of the gate structure;
an ILD structure formed over the source/drain epitaxial structures;
a contact structure formed through the ILD structure over the source/drain epitaxial structures; and
a blocking structure formed in the gate structure and the contact structure,
wherein the blocking structure has an extending bottom portion.

14. The semiconductor structure as claimed in claim 13, wherein a bottom surface of the blocking structure is lower than a bottom surface of the ILD structure.

15. The semiconductor structure as claimed in claim 13, wherein the blocking structure covers the ILD structure.

16. The semiconductor structure as claimed in claim 13, wherein the ILD structure has rounded top corners.

17. The semiconductor structure as claimed in claim 13, wherein the extending bottom portion of the blocking structure protrudes into the substrate.

18. The semiconductor structure as claimed in claim 13, further comprising:
a second ILD structure formed beside the gate structure,
wherein the blocking structure is formed across the ILD structure and the second ILD structure.

19. The semiconductor structure as claimed in claim 13, further comprising:
first spacer layers formed over opposite sides of the gate structure; and
second spacer layers formed over sidewalls of the first spacer layers,
wherein the blocking structure covers top surfaces of the first spacer layers and the second spacer layers.

20. The semiconductor structure as claimed in claim 19, wherein the top surfaces of the second spacer layers are higher than the top surfaces of the first spacer layers.
